(19) United States
(12) Patent Application Publication
(10) Pub. No.: US 2003/0040189 A1
(43) Pub. Date: Feb. 27, 2003

(54) Shallow trench isolation fabrication

(76) Inventors: Ping-Yi Chang, Kaohsiung Hsien (TW); Shu-Li Wu, Nan-Tao City (TW)

Correspondence Address: NAIPO (NORTH AMERICA INTERNATIONAL PATENT OFFICE), P.O. BOX 506, MERRIFIELD, VA, 22116, US

(21) Appl. No.: 09/682,342

(22) Filed: Aug. 22, 2001

(51) Int. Cl. H01L 21/00; H01L 21/302; H01L 21/461; H01L 21/311

(52) U.S. Cl. 438/700; 438/689

(57) ABSTRACT

A stacked mask layer, comprising a pad oxide layer and a stop layer, is formed with at least one opening on a substrate to expose portions of a surface of the substrate. Thereafter, a dry etching process is performed to etch the surface of the substrate through the opening to form a shallow trench. By performing a chemical vapor deposition (CVD) process, a CVD liner layer is formed on both the surface of the stacked mask layer and the surface of the shallow trench. The CVD liner layer is oxidized to form an oxidized liner layer, and a dielectric layer is formed on the oxidized liner layer to fill the shallow trench. By performing a planarization process, both portions of the dielectric layer and the oxidized liner layer atop the stop layer are removed to expose the stop layer. The stop layer is finally removed.

### BACKGROUND OF INVENTION

1. Field of the Invention

The present invention relates to a method of shallow trench isolation (STI) fabrication, and more specifically, to a method of STI fabrication for preventing flaws in corner regions of the shallow trench.

2. Description of the Prior Art

In semiconductor processes, in order to provide good electrical isolation, and to prevent short-circuiting between electric devices on a wafer, a localized oxidation isolation (LOCOS) process, or a shallow trench isolation (STI) process, is used to isolate and protect devices. Since the field oxide layer of the LOCOS process consumes a good deal of area on the wafer, and bird″s beak effects can occur when growing the field oxide, an STI process is typically used in semiconductor processes when the line width is below 0.25 μm. An STI process involves first forming a shallow trench between devices on the wafer, and then filling the trench with an insulating material to obtain an electrical isolation effect between each of the devices on the wafer.

Please refer to FIG. 1 to FIG. 3, which are cross-sectional views of forming a shallow trench isolation (STI) structure according to the prior art. As shown in FIG. 1, a semiconductor wafer 10 has a silicon substrate 12 and a silicon nitride layer 16, with an underlying silicon oxide layer 14 covering the silicon substrate 12. The silicon oxide layer 14 and the silicon nitride layer 16 are used as a pad oxide and a mask, respectively, in following processes. The method of forming an STI structure according to the prior art involves first forming a shallow trench 18 in a predetermined area on the surface of the semiconductor wafer 10 by employing various processes, such as photolithography and anisotropic etching. The shallow trench 18 is positioned in the silicon nitride layer 16 and the silicon oxide layer 14, to a predetermined depth in the silicon substrate 12.

As shown in FIG. 2, lattice defects in the STI structure result due to damage of both the walls and the bottom surface of the shallow trench 18 during an etching process. Thus, a thermal oxidation process, also known as a furnace oxidation process, is performed to oxidize the walls and the bottom surface of the shallow trench 18 at a temperature of 800 to 1000° C. to form a liner oxide layer 22 on the interior surface of the shallow trench 18. Another objective of the thermal oxidation process is corner-rounding of the sharp corner portions located at the interface of the trench 18 as well as at the horizontal surface of the silicon substrate 12, to relieve stress and prevent leakage.

As shown in FIG. 3, chemical vapor deposition (CVD) is performed to form a dielectric layer 20 to cover the surface of the semiconductor wafer 10 and to fill the shallow trench 18 so as to insulate the shallow trench 18. Thereafter, a chemical mechanical polishing (CMP) process is performed to remove portions of the dielectric layer 20. Finally, a chemical solution, such as heated phosphoric acid, is employed to completely remove the silicon nitride layer 16. The surface of the remaining portion of the dielectric layer 20 located within the shallow trench 18 is approximately aligned flush with that of the silicon oxide layer 14, to form a smooth surface on the semiconductor wafer 10 at the end of the STI process.

However, an oxide-recess portion 24 is frequently formed during the anisotropic etching process to form the shallow trench 18 in a predetermined region on the surface of the semiconductor wafer 10. This is due to an etching rate of the silicon oxide layer 14 that is greater than that of the silicon nitride layer 16. The oxide-recess portion 24, not being completed filled with the dielectric layer 20 formed in the subsequent process, causes a flaw 24, leading to electrical malfunctioning of the device, in the corner region 23 of the shallow trench 18. Even if the oxide-recess portion 24 is completely filled by the dielectric layer 20, the density of portions of the dielectric layer 20 filling the oxide-recesses portion 24 is smaller than that of other portions of the dielectric layer 20. A fringing electric field effect thus occurs in the corner region 23 of the shallow trench 18, and in the walls at either side of the shallow trench 18. The high electrical field effect in the shallow trench 18 leads to polar inversion in the corner region 23 of the shallow trench 18, forming a channel with a low threshold voltage, running parallel to the major device. An increase in the current leakage of the device thus occurs, the so-called sub-threshold kink voltage effect. Additionally, the oxide-recess portion 24 also causes over etching in the corner region 23 in a subsequent acid immersion process, further leading to the electrical malfunctioning of the semiconductor device, such as a double hump on an Id/Vg curve. The performance of the semiconductor device is thus adversely affected.

### SUMMARY OF INVENTION

It is therefore a primary object of the present invention to provide a method of shallow trench isolation (STI) fabrication to prevent flaws in corner regions of the shallow trench.

According to the claimed invention, a semiconductor wafer comprises a substrate. A stacked mask layer, comprising a stop layer, having a thickness ranging from 800 to 2500 angstroms, and a pad oxide layer, is then formed with at least one opening to expose portions of a surface of the substrate. A dry etching process is performed to etch the surface of the substrate through the opening to form a shallow trench. By performing a low-pressure chemical vapor deposition (LPCVD) process, a CVD liner layer, composed of silicon nitride and having a thickness no greater than 200 angstroms, is formed on both the surface of the stacked mask layer and the surface of the shallow trench. By performing an in-situ steam growth (ISSG) process, the CVD liner layer is oxidized to form an oxidized liner layer. A dielectric layer is then formed on the oxidized liner layer to fill the shallow trench. Thereafter, a planarization process is performed to remove both portions of the dielectric layer and the oxidized liner layer atop the stop layer to expose the stop layer. Finally, the stop layer is removed.

It is an advantage of the present invention that the CVD liner layer completely fills the oxide-recess portion. Over etching of the corner regions, caused by heated phosphoric acid in the subsequent process of removing the stop layer, is thus prevented, thereby avoiding electrical malfunctioning of a semiconductor device, such as the double hump on the Id/Vg curve. The sub-threshold kink voltage effect is thus prevented as well. Consequently, the electrical isolation abilities and the reliability of the device are all significantly improved.

These and other objectives of the present invention will no doubt become obvious to those of ordinary skill in the art after reading the following detailed description of the preferred embodiment, which is illustrated in the multiple figures and drawings.

### BRIEF DESCRIPTION OF DRAWINGS

FIG. 1 to FIG. 3 are cross-sectional views of forming a shallow trench isolation (STI) structure according to the prior art.

FIG. 4 to FIG. 9 are cross-sectional views of forming a shallow trench isolation (STI) structure according to the present invention.

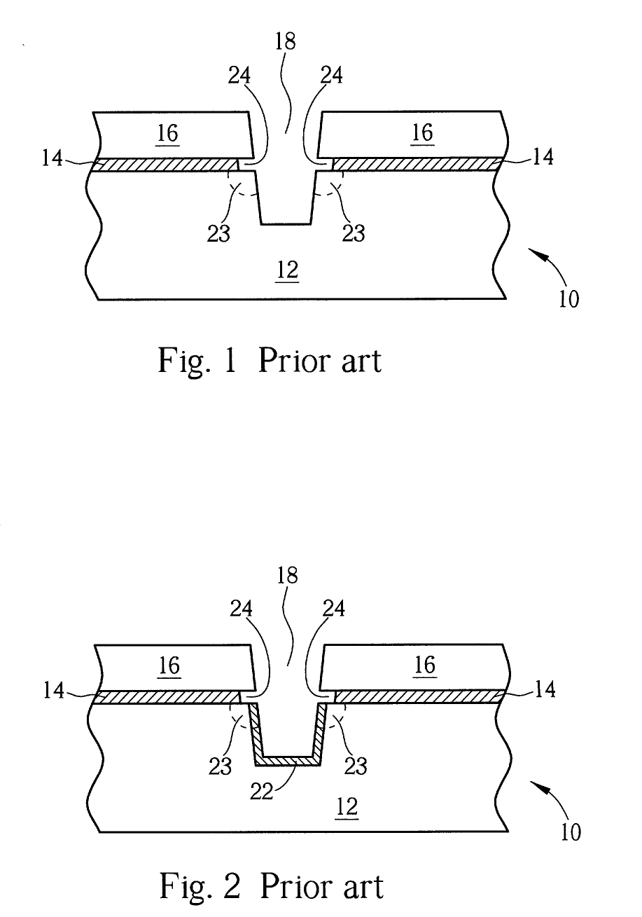

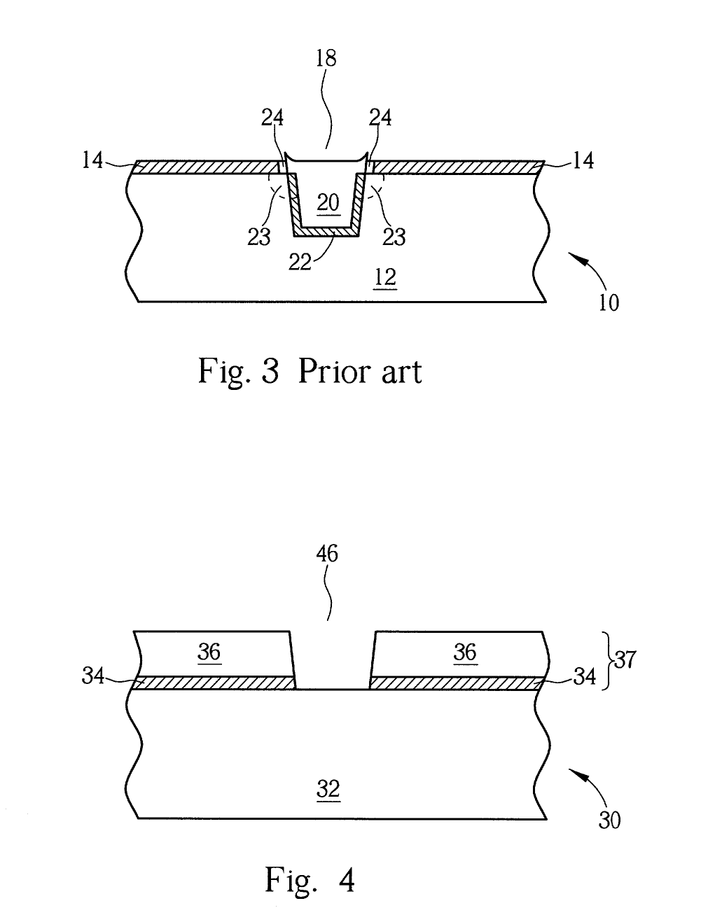

### DETAILED DESCRIPTION

Please refer to FIG. 4 to FIG. 9, which are cross-sectional views of forming a shallow trench isolation (STI) structure according to the present invention. As shown in FIG. 4, a semiconductor wafer 30 comprises a silicon substrate 32 and a stacked mask layer. The stacked mask layer comprises a pad oxide layer 34 and a stop layer 36, composed of a silicon nitride layer, and has at least one opening 46 to expose portions of a surface of the silicon substrate 32.

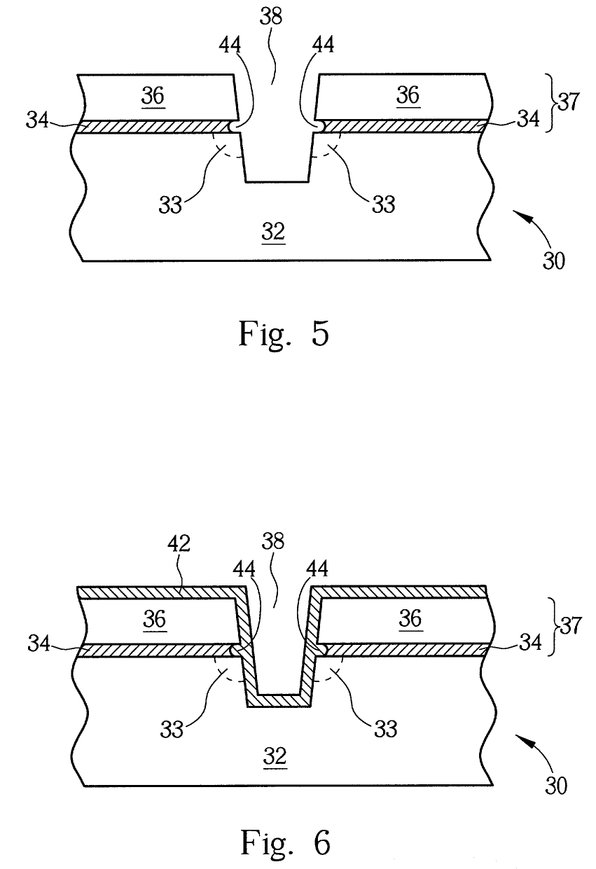

As shown in FIG. 5, an anisotropic dry etching process is performed to etch the surface of the silicon substrate 32 through the opening 46 to form a shallow trench 38 at a predetermined depth in the silicon substrate 32. Simultaneously, an oxide-recess portion 44 is formed in a corner region 33 of the shallow trench 38 due to an etching rate of the pad oxide layer 34 being greater than that of the stop layer 36. The oxide-recess portion 44 generally causes a flaw in the corner region 33 of the shallow trench 38 in subsequent processes, which adversely affects the performance of the semiconductor device.

As shown in FIG. 6, a low-pressure chemical vapor deposition (LPCVD) is performed to form a CVD liner layer 42, composed of silicon nitride and having a thickness no greater than 200 angstroms. The oxide-recess portion 44 in the corner region 33 of the shallow trench 38 is filled by the CVD liner layer 42. Alternatively, the CVD liner layer 42 may be composed of polysilicon or amorphous silicon, with a thickness no greater than 200 angstroms, in another embodiment of the present invention.

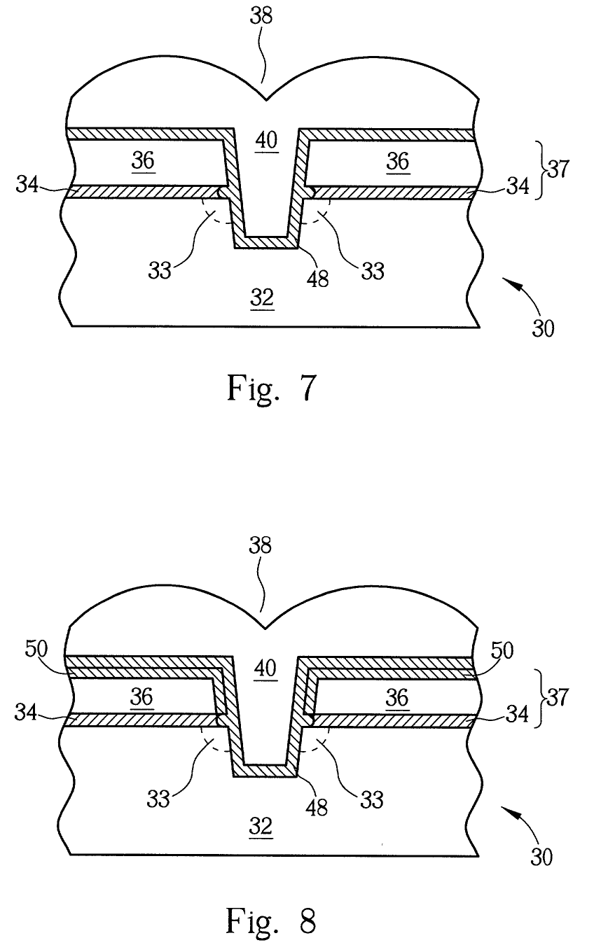

As shown in FIG. 7, an oxidation process, an in-situ steam growth (ISSG) process with oxygen radicals and hydrogen radicals and balanced by nitrogen, is performed at a temperature greater than 800° C. to oxidize the CVD liner layer 42 to form an oxidized liner layer 48. The hydrogen flow amounts to less than 50% of the total flow amount of both the hydrogen and oxygen. The volume of the oxidized liner layer 48 is approximately 1.3 to 1.5 times the volume of the CVD liner layer 42 due to the expansion of the CVD liner layer 42 caused by the oxidation process. A dielectric layer 40 is then formed on the oxidized liner layer to fill the shallow trench 38. As shown in FIG. 8, portions of the stop layer 36, composed of silicon nitride, are simultaneously oxidized to form a silicon oxide layer 50 as the CVD liner layer 42 is oxidized to form the oxidized liner layer 48.

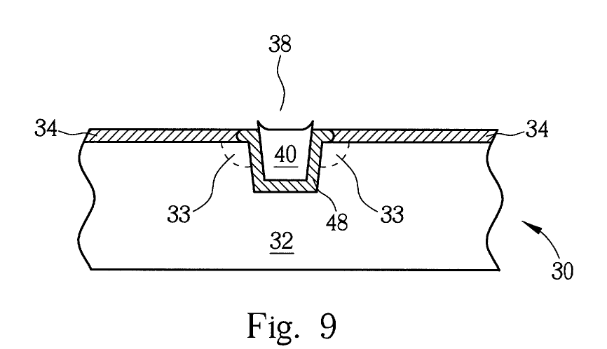

As shown in FIG. 9, a planarization process is performed to remove both portions of the dielectric layer 40 and the oxidized liner layer 48 atop the stop layer 36 to expose the stop layer 36. Finally, a chemical solution, such as heated phosphoric acid, is employed to completely remove the stop layer 36. The surface of the remaining portions of the dielectric layer 40 located within the shallow trench 38 is approximately aligned flush with that of the pad oxide layer 34, to form a smooth surface on the semiconductor layer 30 at the end of the STI process.

The ISSG process, a sub-atmophericpressure wet rapid thermal oxidation (RTP) process, can be performed prior to the formation of the isolation layer 40 as well. The ISSG process can be performed in a single wafer type RTP chamber, such as Applied Materials Company's RTP XEplus Centura machine, having 15 to 20 parallel arrayed tungsten halogen lamps to rapidly raise the temperature of the wafer to a required value.

In comparison with the prior art, an ISSG process is employed in the present invention to oxidize the CVD liner layer 42 to form the oxidized liner layer 48 having a better etch resistance. In addition, the CVD liner layer 42 completely fills the oxide-recess portion 44. Sub-threshold kink voltage effects are thus prevented. Additionally, the oxide-recess portion 44 in the corner region 33 of the shallow trench 38 is completely filled by the oxidized liner layer 48, which has a better etch resistance. The corner region 33 is thus saved from over etching in the subsequent process of removing the stop layer 36 by using heated phosphoric acid, which might otherwise lead to electrical malfunctioning of a semiconductor device, such as the double hump on the Id/Vg curve. The electrical isolation abilities and the reliability of the device are thus improved by forming an oxidized liner layer 48 without consuming the silicon substrate 32.

Those skilled in the art will readily observe that numerous modifications and alterations of the device may be made while retaining the teachings of the invention. Accordingly, the above disclosure should be construed as limited only by the metes and bound of the appended claims.

What is claimed is:

1. A method of shallow trench isolation (STI) fabrication comprising:
providing a substrate;
forming a stacked mask layer, the stacked mask layer comprising a pad oxide layer and a stop layer, the stacked mask layer having at least one opening to expose portions of a surface of the substrate;
performing a dry etching process to etch the surface of the substrate through the opening to form a shallow trench;
forming a chemical vapor deposition (CVD) liner layer on both the surface of the stacked mask layer and the surface of the shallow trench;
oxidizing the CVD liner layer to form an oxidized liner layer;
forming a dielectric layer on the oxidized liner layer to fill the shallow trench;
performing a planarization process to remove both portions of the dielectric layer and the oxidized liner layer atop the stop layer to expose the stop layer; and
removing the stop layer.

2. The method of claim 1 wherein the stop layer is a silicon layer.

3. The method of claim 2 wherein the silicon layer has a thickness ranging from 800 to 2500 angstroms.

4. The method of claim 1 wherein the stop layer is a silicon nitride layer.

5. The method of claim 1 wherein the CVD liner layer is composed of silicon nitride.

6. The method of claim 1 wherein the CVD liner layer is composed of silicon.

7. The method of claim 6 wherein the silicon layer is a polysilicon layer.

8. The method of claim 6 wherein the silicon layer is an amorphous silicon layer.

9. The method of claim 5 wherein the CVD liner layer is formed by performing a low pressure chemical vapor deposition (LPCVD) process.

10. The method of claim 5 wherein the CVD liner layer has a thickness no greater than 200 angstroms.

11. The method of claim 5 wherein the CVD liner layer is oxidized by performing an in-situ steam growth (ISSG) process.

12. The method of claim 1 wherein the substrate is a silicon substrate.
